(19) United States
(12) Patent Application Publication
(10) Pub. No.: US 2010/0059102 A1
(43) Pub. Date: Mar. 11, 2010

(54) SOLAR CELL MODULE

(75) Inventors: Toshio Yagiura, Osaka (JP); Satoru Ogasahara, Osaka (JP)

Correspondence Address: DITTHAVONG MORI & STEINER, P.C., 918 Prince Street, Alexandria, VA, 22314, US

(73) Assignee: Sanyo Electric Co., Ltd., Moriguchi-shi (JP)

(21) Appl. No.: 12/596,746

(22) PCT Filed: Apr. 8, 2008
(86) PCT No.: PCT/JP2008/056919

§ 371 Date: Nov. 16, 2009

(30) Foreign Application Priority Data
Apr. 20, 2007 (JP) 2007-112266
Sep. 3, 2007 (JP) 2007-228151

(51) Int. Cl. H01L 31/042

(52) U.S. Cl. 136/244

(57) ABSTRACT

A solar cell module 1 includes a transparent light-receiving-surface protection member 11, a rear-surface protection member 14 placed at the rear surface side of the light-receiving-surface protection member 11, and a plurality of solar cells bonded between the light-receiving-surface protection member 11 and the rear-surface protection member 14. The rear-surface protection member 14 has a planar shape larger than that of the light-receiving-surface protection member. Further, the rear-surface protection member 14 has a smaller amount of displacement for an external load than that of the light-receiving-surface protection member, or has higher strength against impact than that of the light-receiving-surface protection member.

### TECHNICAL FIELD

The present invention relates to a solar cell module including a light-receiving-surface protection member and a rear-surface protection member.

### BACKGROUND ART

Solar cells can directly convert sunlight, which is a clean and unlimitedly-supplied energy source, into electricity, and thus are expected as one of new energy sources. As such a solar cell, the development of a thin-film solar cell has been in progress. The thin-film solar cell is mainly composed of a thin film semiconductor material such as an amorphous silicon semiconductor, a microcrystalline silicon semiconductor or CuInSe.

As an example of such a thin-film solar cell, a structure of a conventional solar cell module using an amorphous silicon thin-film solar cell will be described with reference to FIG. 1 (see JP-A 11-135811, for example).

A solar cell module 100 includes a light-receiving-surface protection member 101, a solar cell layer 102, a resin material 103 such as EVA or PVB, and a rear-surface protection member 104. The light-receiving-surface protection member 101 is formed of a glass plate and a SnO₂ (transparent conductive film) layer formed on the glass plate by a thermal CVD method. The solar cell layer 102 is a so-called integrated solar cell formed on the SnO₂ layer, and is formed of: a semiconductor layer having a pin structure mainly composed of an amorphous silicon semiconductor; and a rear-surface electrode formed on the semiconductor layer. The solar cell layer 102 described above is bonded between the light-receiving-surface protection member 101 and the rear-surface protection member 104 with the resin material 103. The rear-surface protection member 104 is made of a glass plate, a metal plate, a resin film or the like.

The glass plate constituting the light-receiving-surface protection member 101 has a brittle and fragile property, and thus needs to enhance its strength. Conceivable ways to enhance the strength of a glass plate include reducing the area of the glass plate, increasing the thickness of the glass plate, and the like. However, the reduction in the area of a glass plate prevents a higher power output of the solar cell module 100. On the other hand, the increase in the thickness of a glass plate results in an increase in total weight of the solar cell module 100.

Meanwhile, there is disclosed a technique of enhancing the strength of a glass plate without increasing the thickness of the glass plate by executing a reinforcement process on the glass plate after forming a SnO₂ layer on the glass plate (see Japanese Patent No. 2615147).

### DISCLOSURE OF THE INVENTION

One of methods having been heretofore devised to prevent the damage of the solar cell module 100 is to enhance the strength of a frame 105 holding the solar cell module 100 and thereby to reduce the displacement of the light-receiving-surface protection member 101. However, there is a report on the damage of the solar cell module 100 which is peculiar to a portion held by the frame 105.

FIG. 2 schematically shows a state of a portion of the solar cell module 100 held by the frame 105 in a case where an external force F is applied on the solar cell module 100. As shown in FIG. 2, the light-receiving-surface protection member 101 and the rear-surface protection member 104, which are designed to withstand a predetermined displacement, will not be broken even if a displacement x occurs. However, due to the combination of certain factors, the degree of displacement may go beyond the allowable range in which a covering member 106 can exert its cushioning effect. In this case, the rear-surface protection member 104 and the light-receiving-surface protection member 101 are sometimes brought into contact with end portions 105a and 105b of the frame 105, thereby damaging the light-receiving-surface protection member 101 and the rear-surface protection member 104. Likewise, in this case, an end portion 101a of the light-receiving-surface protection member 101 and an end portion 104a of the rear-surface protection member 104 are sometimes brought into contact with the inner wall of the frame 105 and damaged.

Furthermore, for example, the solar cell module may be shipped with no frame attached thereto in the manufacturing step (FIG. 3) according to the user' s needs. Even though elaborately packaged, such a frameless module is highly possibly damaged during transportation at corner portions of the solar cell module 100, particularly at corner portions (W1 and W2 in FIG. 3) of the light-receiving-surface protection member 101 located on the upper side thereof.

Thus, an object of the present invention is to provide a solar cell module capable of suppressing occurrence of damage.

To achieve the above-described object, an aspect of the present invention provides a solar cell module comprising a transparent light-receiving-surface protection member including a light-receiving surface and a rear surface provided on a side opposite to the light-receiving surface; a rear-surface protection member placed at the rear surface side of the light-receiving-surface protection member; and a plurality of solar cells bonded between the light-receiving-surface protection member and the rear-surface protection member, wherein the rear-surface protection member has a planar shape larger than that of the light-receiving-surface protection member, and has a smaller amount of displacement for an external load than that of the light-receiving-surface protection member.

Further, an aspect of the present invention provides a solar cell module comprising a transparent light-receiving-surface protection member including a light-receiving surface and a rear surface provided on a side opposite to the light-receiving surface; a rear-surface protection member placed at the rear surface side of the light-receiving-surface protection member; and a plurality of solar cells bonded between the light-receiving-surface protection member and the rear-surface protection member, wherein the rear-surface protection member has a planar shape larger than that of the light-receiving-surface protection member, and has higher strength against impact than that of the light-receiving-surface protection member.

According to the aspect of the present invention, the rear-surface protection member may be made of glass.

According to the aspect of the present invention, on a projection plane substantially parallel to the light-receiving surface of the light-receiving-surface protection member, a frame may hold a portion, in which the rear-surface protection member does not overlap the light-receiving-surface protection member, of the rear-surface protection member.

According to the aspect of the present invention, the light-receiving-surface protection member may be smaller than an inside dimension of the frame.

According to the aspect of the present invention, a corner portion formed between the light-receiving surface of the light-receiving-surface protection member and an end surface continuous to the light-receiving surface may be covered with a resin material.

### BRIEF DESCRIPTION OF THE DRAWINGS

FIG. 1 is a cross-sectional view of a conventional solar cell module.

FIG. 2 is an enlarged view for explaining a portion held by a frame of the conventional solar cell module.

FIG. 3 is a cross-sectional view of the conventional solar cell module having a frameless structure.

FIG. 4 is a cross-sectional view of a solar cell module according to an embodiment of the present invention.

FIG. 5 is a cross-sectional view of the solar cell module according to the embodiment of the present invention having a frameless structure.

FIG. 6 is an external plan view of the solar cell module according to the embodiment of the present invention seen from a light-incident side.

FIG. 7 is a cross-sectional view of a solar cell module according to an embodiment of the present invention.

FIG. 8 is an external plan view of the solar cell module according to the embodiment of the present invention seen from a light-incident side.

FIG. 9 is a cross-sectional view of a solar cell module according to the embodiment of the present invention.

FIG. 10 is a cross-sectional view of a solar cell module according to an embodiment of the present invention.

### BEST MODES FOR CARRYING OUT THE INVENTION

Embodiments of the present invention will be described below with reference to the drawings. In the following description of the drawings, the same or similar parts will be denoted by the same or similar reference numerals. However, it should be noted that the drawings are schematic and that their dimensional ratios and the like are different from actual ones. Thus, specific dimensions and the like should be determined by referring to the description below. Naturally, there are portions where dimensional relationships and ratios between the drawings are different.

### First Embodiment

By using FIG. 4 to FIG. 7, a description will be given of a solar cell module shown as an embodiment of the present invention.

As shown in FIG. 4, in a solar cell module 1, a solar cell layer 12 is formed on a light-receiving-surface protection member 11. The light-receiving-surface protection member 11 includes a light-receiving surface and a rear surface provided on a side opposite to the light-receiving surface.

The light-receiving surface of the light-receiving-surface protection member 11 is made of a glass plate (blue plate glass, for example). The rear surface of the light-receiving-surface protection member 11 is composed of a SnO₂ (tin oxide) layer formed on the glass plate by a thermal CVD method. The SnO₂ layer serves as a transparent electrode.

The solar cell layer 12 is formed on the rear surface (SnO₂ layer) of the light-receiving-surface protection member 11. The solar cell layer 12 is composed of a semiconductor layer formed on the SnO₂ layer, and a rear-surface electrode formed on the semiconductor layer. The semiconductor layer has at least one semiconductor pin junction mainly composed of, for example, an amorphous silicon semiconductor, a microcrystalline silicon semiconductor, or the like. The semiconductor layer is formed by a sputtering method, a CVD method, or the like. The semiconductor layer according to this embodiment is formed by sequentially stacking: a first semiconductor layer having a semiconductor pin junction mainly composed of an amorphous silicon semiconductor; and a second semiconductor layer having a semiconductor pin junction mainly composed of a microcrystalline silicon semiconductor. Table 1 shows an example of film-forming conditions applied when the semiconductor layer is formed by a plasma CVD method.

TABLE 1
CVD Condition Table

| | Substrate | Gas Flow | Reaction | | Film |
|---|---|---|---|---|---|
| | Temperature | Rate | Pressure | RF Power | Thickness |
| Layer | (° C.) | (sccm) | (Pa) | (W) | (nm) |
| P Layer | 180 | SiH₄: 300 | 106 | 10 | 10 |
| | | CH₄: 300 | | | |
| | | H₂: 2000 | | | |
| | | B₂H₆: 3 | | | |
| I Layer | 200 | SiH₄: 300 | 106 | 20 | 300 |
| | | H₂: 2000 | | | |
| N Layer | 180 | SiH₄: 300 | 133 | 20 | 20 |
| | | H₂: 2000 | | | |
| | | PH₃: 5 | | | |
| P Layer | 180 | SiH₄: 10 | 106 | 10 | 10 |
| | | H₂: 2000 | | | |
| | | B₂H₆: 3 | | | |
| I Layer | 200 | SiH₄: 100 | 133 | 20 | 2000 |
| | | H₂: 2000 | | | |
| N Layer | 200 | SiH₄: 10 | 133 | 20 | 20 |
| | | H₂: 2000 | | | |
| | | PH₃: 5 | | | |

The rear-surface electrode of the solar cell layer 12 is formed of a transparent conductive layer, such as an ITO layer or a ZnO layer, and a light-reflective metal layer, such as Al or Ag, which are stacked on the semiconductor layer (second semiconductor layer in this embodiment).

The solar cell layer 12 is divided into multiple solar cells by using a publicly-known laser patterning method. The multiple solar cells are electrically connected to each other in series to form a so-called integrated solar cell structure.

Here, a description will be given of an example of a method for manufacturing the solar cell module 1 according to this embodiment. First, the solar cell layer 12 described above is formed on the light-receiving-surface protection member 11. Next, a stacked body is formed by sequentially stacking a rear-surface protection member 14 larger in size than the light-receiving-surface protection member 11, a filling member such as EVA, the solar cell layer 12, and the light-receiving-surface protection member 11. Then, the stacked body is integrated by a laminator. After this process is over, a terminal box (not shown) through which an electric output may be taken out is installed. Lastly, a frame 15 is installed in such a manner as to hold the rear-surface protection member 14 with a bonding member 16 such as silicon. In this event, a covering member 17 is filled between the light-receiving-surface protection member 11 and the frame 15.

In this respect, the rear-surface protection member 14 according to this embodiment is larger in size than the light-receiving-surface protection member 11. Moreover, the rear-surface protection member 14 has a smaller amount of displacement for an external load than that of the light-receiving-surface protection member 11. Further, the rear-surface protection member 14 has higher strength against impact than that of the light-receiving-surface protection member 11. As the rear-surface protection member 14, transparent blue plate (soda-lime) tempered glass having sides approximately 20 mm larger than those of the light-receiving-surface protection member 11 can be used, for example. As shown in FIG. 4, end portions of the rear-surface protection member 14 are held by the frame 15. The structures of the rear-surface protection member 14 and the light-receiving-surface protection member 11 will be described later.

As the filling member 13, an ethylene-based resin such as EVA, PVB, butyl rubber and an ethylene-ethyl acrylate copolymer resin, and a resin material such as silicon, a urethane resin, an acrylic-based resin and an epoxy resin may be used alone or may be used in combination.

An aluminum frame or the like may be used as the frame 15. However, the frame 15 is not limited to this.

As the bonding member 16, a resin material such as silicon, polycarbonate, polystyrene, a urethane resin, cellulose acetate, a phenol resin, an epoxy resin, an acrylic-based resin and butyl rubber may be used alone or may be used in combination. Alternatively, the bonding member 16 may be a general rubber-based or olefin-based thermoplastic elastomer. Any material can be used as long as it prevents the solar cell module 1 from dropping off the frame 15 and from being broken when a load is applied thereon.

As the covering member 17, a resin material such as silicon, polycarbonate, polystyrene, a urethane resin, cellulose acetate, a phenol resin, an epoxy resin, an acrylic-based resin and butyl rubber may be used alone or may be used in combination.

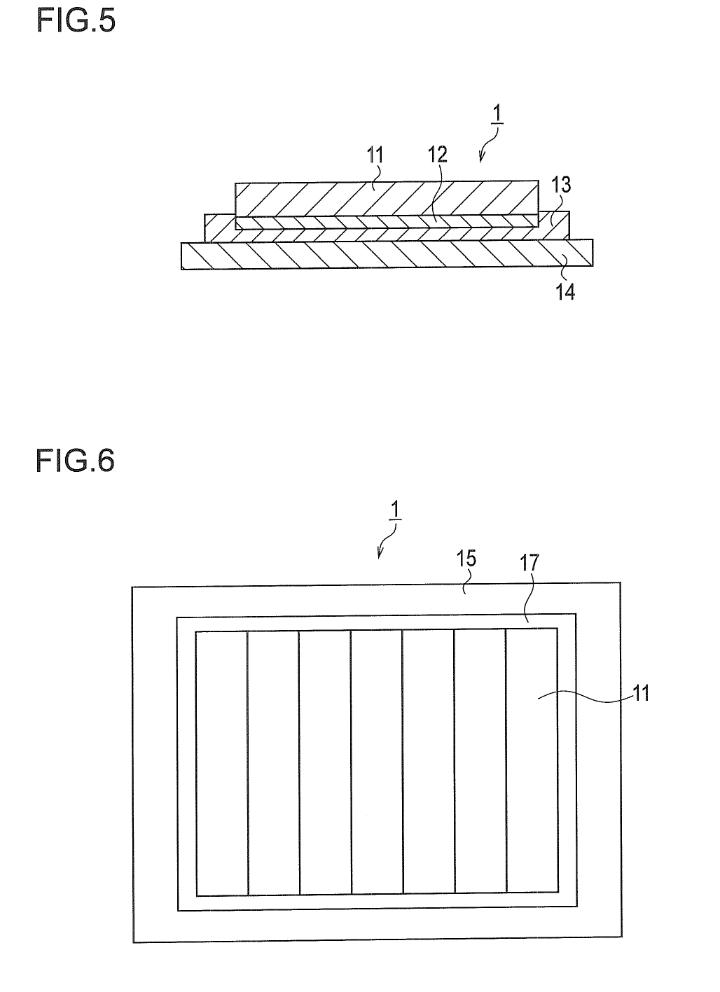

FIG. 5 shows a state before the frame 15 is attached to the solar cell module 1. The rear-surface protection member has a planar shape larger than that of the light-receiving-surface protection member 11. Accordingly, on a projection plane substantially parallel to the light-receiving surface of the light-receiving-surface protection member 11, the outer periphery of the rear-surface protection member 14 is located outside the outer periphery of the light-receiving-surface protection member 11. In other words, the rear-surface protection member 14 forms the outer periphery of the solar cell module 1, the rear-surface protection member 14 having a smaller amount of displacement than that of a glass plate constituting the light-receiving-surface protection member 11 and having higher strength against impact than that of the glass plate.

FIG. 6 is a plan view showing the solar cell module 1 according to this embodiment seen from the light-receiving surface side of the light-receiving-surface protection member 11. As shown in FIG. 6, the light-receiving-surface protection member 11 does not get into the inside of the frame 15, and is not in contact with the frame 15. Thus, end portions of the light-receiving-surface protection member 11 are not covered with the frame 15.

### (Load Test)

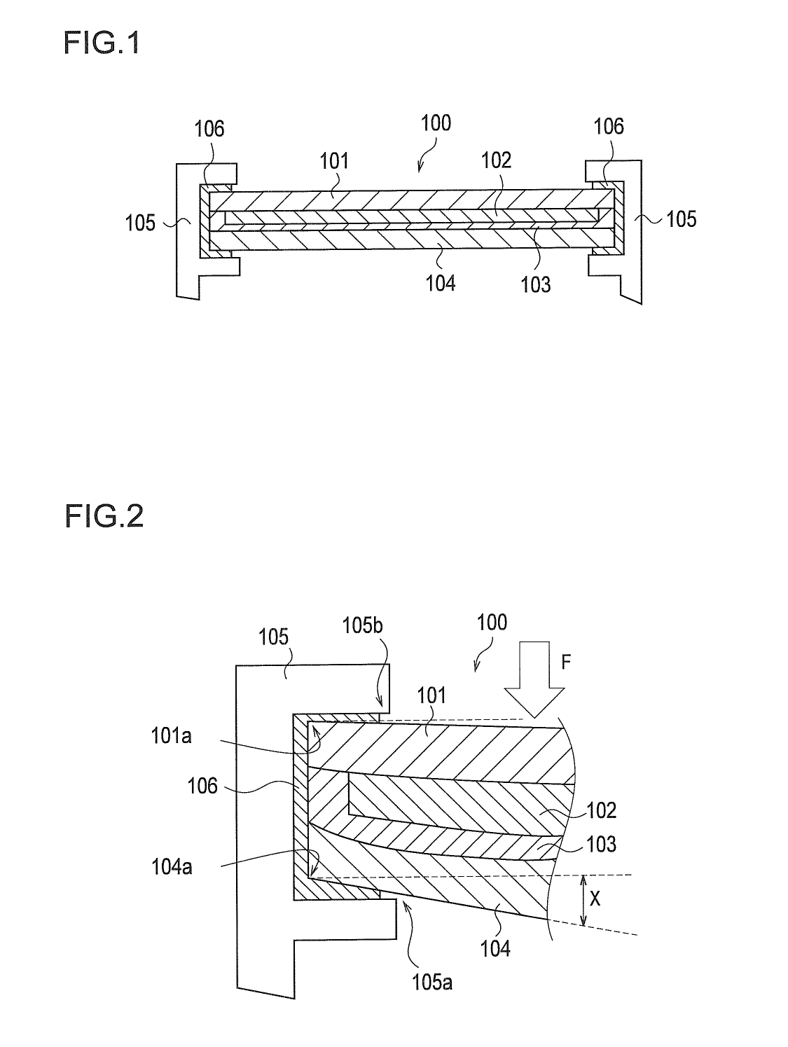

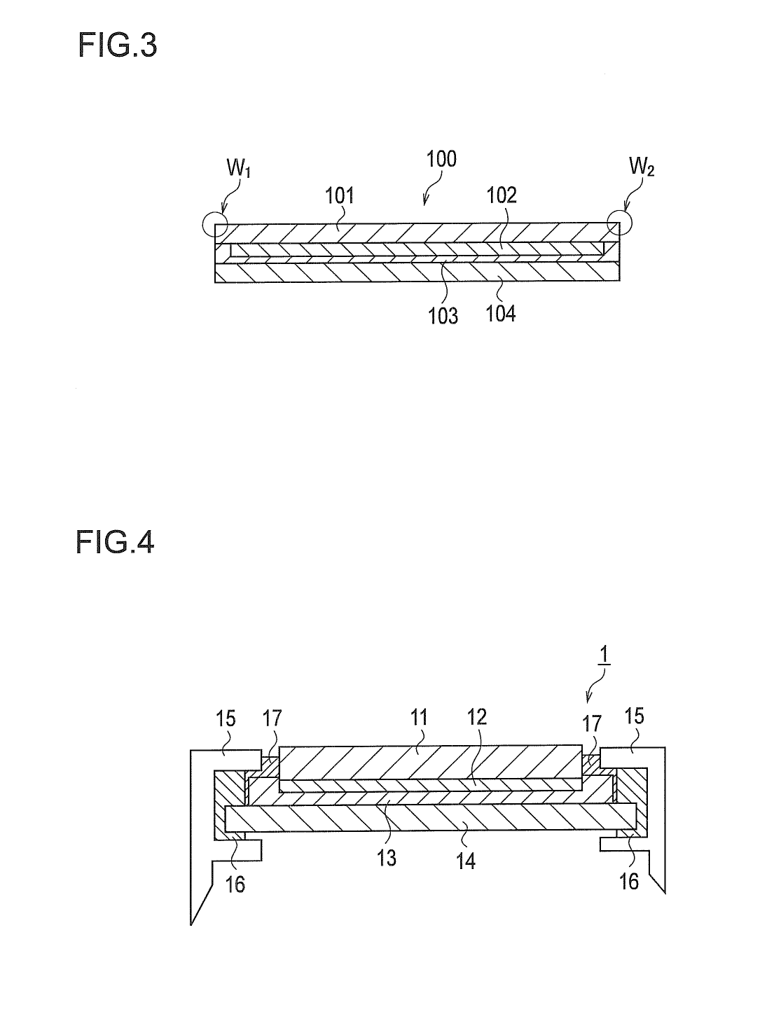

The strength of the solar cell module 1 having the structure shown in FIG. 4 and that of the solar cell module 100 having the structure shown in FIG. 1 were measured in accordance with a mechanical load test for solar cells defined in IEC 61215 10.16. Specifically, approximately 1 m square solar cell modules (five modules to be tested) were applied with a load of 2400 Pa. As a result, damage was observed in all the five test modules of the solar cell module 100 having the conventional structure. By contrast, no damage was observed in all the five test modules of the solar cell module 1 having the structure shown in FIG. 4.

The above-described results were obtained due to the following reason. Specifically, in this embodiment, tempered glass is used as the rear-surface protection member 14, the tempered glass being one size larger than a glass plate which is used as the light-receiving-surface protection member 11 and having a smaller amount of displacement for a load than that of the glass plate. Moreover, in this embodiment, only the rear-surface protection member 14 is held by the frame 15. As a result, the amount of displacement for a load of the entire solar cell module 1 was reduced, so that the damage of the solar cell module 1 was suppressed.

### (Effects and Advantages)

In the solar cell module 1 according to this embodiment, the rear-surface protection member 14 has a planar shape larger than that of the light-receiving-surface protection member 11.

Accordingly, the solar cell module 1 can be held by causing the frame 15 to hold end portions of the rear-surface protection member 14. This makes it possible to prevent the damage of the light-receiving-surface protection member 11 which would otherwise occur if end portions of the light-receiving-surface protection member 11 are brought into contact with the frame 15 when the solar cell module 1 is deformed.

Moreover, the end portions of the light-receiving-surface protection member 11 can be prevented from being damaged by receiving impact when the solar cell module 1 is being transported with no frame 15 attached thereto.

Additionally, the light-receiving-surface protection member 11 having a small planar shape can be used, as compared with a case of causing the frame 15 to hold the light-receiving-surface protection member 11 and the rear-surface protection member 14. For this reason, the manufacturing cost of the solar cell module 1 can be reduced. Generally, a glass plate having a transparent electrode (SnO₂ layer) formed thereon is expensive. Hence, it is particularly effective to make the planar shape of the light-receiving-surface protection member 11 smaller.

Further, in the solar cell module 1 according to this embodiment, the rear-surface protection member 14 has a smaller amount of displacement for an external load than that of the light-receiving-surface protection member 11. In other words, the amount of displacement for an external load of the light-receiving-surface protection member 11 can be reduced to that of the rear-surface protection member 14. Accordingly, the thickness of the light-receiving-surface protection member 11 can be made smaller, thereby reducing the manufacturing cost of the solar cell module 1. In addition, it is possible to suppress the damage of the rear-surface protection member 14 occurring if the end portions of the rear-surface protection member 14 are brought into contact with the frame 15 when the frame 15 holds the end portions of the rear-surface protection member 14.

Furthermore, in the solar cell module 1 according to this embodiment, the rear-surface protection member 14 has higher strength against impact than that of the light-receiving-surface protection member 11. This makes it possible to suppress the damage of the end portions of rear-surface protection member 14 occurring if the end portions of the rear-surface protection member 14 receive impact when the solar cell module 1 is being transported with no frame 15 attached thereto. Moreover, even though the strength of the frame 15 is relatively low, the strength of the complex of the rear-surface protection member 14 and the frame 15 is maintained as long as the strength of the rear-surface protection member 14 is relatively high. For this reason, the frame 15 may have low strength, that is, may have a simple structure, thereby reducing the manufacturing cost of the solar cell module 1.

Moreover, in this embodiment, the rear-surface protection member 14 is a transparent glass member. Accordingly, so-called bifacial solar cells can be used as the multiple solar cells (solar cell layer 12).

Additionally, in this embodiment, the light-receiving-surface protection member 11 has a planar shape smaller than the inside dimension of the frame 15. For this reason, the end portions of the solar cell layer 12 which is formed on the light-receiving-surface protection member do not get into the inside of the frame 15. This makes it possible for the solar cell module 1 to generate electricity by using the substantially whole surface of the solar cell layer 12. Consequently, the use efficiency of the solar cell layer 12 can be improved as compared to the case where the end portions of the solar cell layer 12 get into the inside of the frame 15.

### Second Embodiment

Next, a second embodiment of the present invention will be described with reference to the drawings.

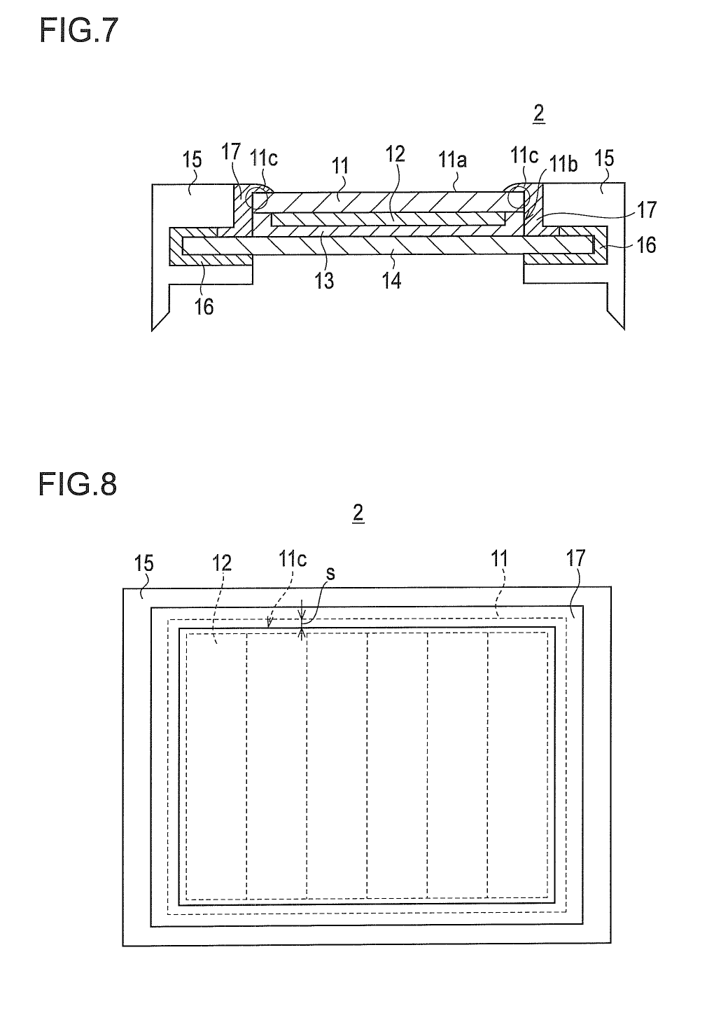

As the rear-surface protection member 14, a solar cell module 2 shown in FIG. 7 includes blue plate (soda-lime) tempered glass having sides larger than those of the light-receiving-surface protection member 11. In the solar cell module 2, the filling member 13 such as EVA and the light-receiving-surface protection member 11 having the solar cell layer 12 formed thereon are sequentially stacked on the rear-surface protection member 14, and then they are integrated by the laminator. Further, the frame 15 holds the end portions of the rear-surface protection member 14 with the bonding member 16. In the solar cell module 2, the covering member 17 is filled between the light-receiving-surface protection member 11 and the frame 15, and covers the end portions of the light-receiving-surface protection member 11.

Here, the end portions of the light-receiving-surface protection member 11 at least include: end portions of a principal surface 11a located on the light-receiving surface side of the light-receiving-surface protection member 11; end surfaces 11b continuous to the principal surface 11a; and corner portions 11c located between the principal surface 11a and each end surface 11b.

FIG. 8 is a plan view showing the solar cell module 2 seen from the principal surface 11a side of the light-receiving-surface protection member 11. As shown in FIG. 8, the cover portions 11c of the light-receiving-surface protection member 11 are covered with the covering member 17 at the inner side of the frame 15. In this way, the light-receiving-surface protection member 11 is covered with the covering member 17 at a region S. The region S ranges from the outer periphery of the principal surface 11a to the inner side thereof toward a center portion of the light-receiving-surface protection member 11 by a predetermined width. Note that, in this case, the covering member 17 preferably does not overlap the solar cell layer 12 when seen from the light-receiving surface side.

The resin materials described above can be used as the filling member 13, the bonding member 16 and the covering member 17. The same material may be used for the bonding member 16 and the covering member 17.

Here, when a highly gas-permeable material such as EVA is used as the filling member 13, for example, it is preferable to select butyl rubber as the covering member 17, the butyl rubber having relatively low gas permeability among the resin materials described above. This prevents EVA from being exposed to exterior environment, thus enhancing the effect of preventing entry of water and the like.

### (Effects and Advantages)

In the solar cell module 2 according to this embodiment, the corner portions 11c of the light-receiving-surface protection member 11 are covered with the covering member 17. In other words, the corner portions 11c of the light-receiving-surface protection member 11, which are likely to be damaged, are protected by the resin material. This makes it possible to further suppress the damage of the corner portions 11c of the light-receiving-surface protection member 11 due to the application of impact on the corner portions 11c.

### (Modification of Second Embodiment)

Next, a modification of the second embodiment will be described with reference to the drawing.

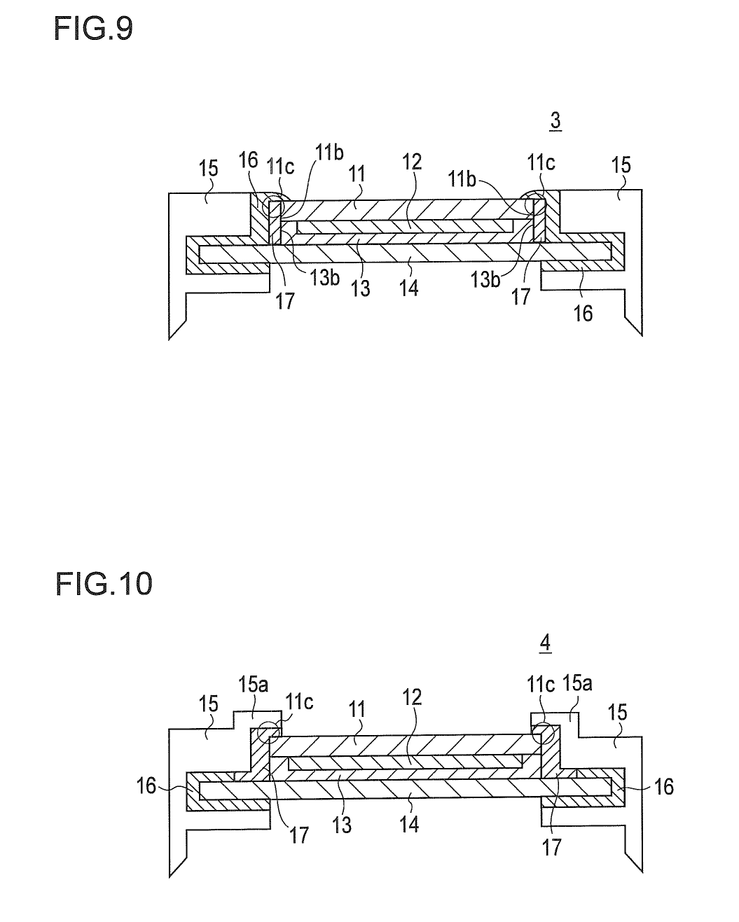

In a solar cell module 3 shown in FIG. 9, the end surfaces 11b of the light-receiving-surface protection member 11 and end surfaces 13b of the filling member 13 are protected by the covering member 17. Moreover, the bonding member 16 used for bonding the rear-surface protection member 14 to the frame 15 covers the cover portions 11c of the light-receiving-surface protection member 11. In other words, in the solar cell module 3, the corner portions 11c of the light-receiving-surface protection member 11 are covered with the bonding member 16. As similar to the solar cell module 2 shown in FIG. 7 and FIG. 8, the bonding member 16 which covers the region S (see FIG. 8) preferably does not overlap the solar cell layer 12.

The resin materials described above can be used as the filling member 13, the bonding member 16 and the covering member 17. The same material may be used for the bonding member 16 and the covering member 17.

### (Effects and Advantages)

In the solar cell module 3 according to this embodiment, the corner portions 11c of the light-receiving-surface protection member 11 are covered with the bonding member 16. In other words, the corner portions 11c of the light-receiving-surface protection member 11, which are likely to be damaged, are protected by the resin material. This makes it possible to further suppress the damage of the corner portions 11c of the light-receiving-surface protection member 11 due to the application of impact on the corner portions 11c.

### Third Embodiment

A solar cell module 4 shown in FIG. 10 is characterized in that the frame 15 includes a protection portion 15a which protects the end portions of the light-receiving-surface protection member 11. Note, however, that the frame 15 has a structure of holding the rear-surface protection member 14, and thus the protection portion 15a does not substantially hold the light-receiving-surface protection member 11. The covering member 17 is filled between the light-receiving-surface protection member 11 and the frame 15, and covers the corner portions 11c of the light-receiving-surface protection member 11.

Here, the protection portion 15a of the frame 15 preferably does not overlap the solar cell layer 12 when seen from the light-receiving surface side of the light-receiving-surface protection member 11.

The resin materials described above can be used as the filling member 13, the bonding member 16 and the covering member 17. The same material may be used for the bonding member 16 and the covering member 17.

### (Effects and Advantages)

In the solar cell module 4 according to this embodiment, the corner portions 11c of the light-receiving-surface protection member 11 are protected by the protection portion 15a provided to the frame 15. Moreover, the corner portions 11c are covered with the covering member 17. In this way, the corner portions 11c of the light-receiving-surface protection member 11 are protected by the protection portion 15a and the covering member 17. This makes it possible to further suppress the damage of the corner portions 11c due to the application of impact thereon.

### (Modification of Third Embodiment)

The solar cell module 4 shown in FIG. 10 has been described on the basis of the structure of the solar cell module 2 shown in FIG. 7. Alternatively, the solar cell module 4 may have a structure based on the solar cell module 3 shown in FIG. 9. To be more specific, the end surfaces 11b of the light-receiving-surface protection member 11 and the end surfaces 13b of the filling member 13 may be protected by the covering member 17. Moreover, the bonding member 16 which is used for fixing the frame 15 holding the rear-surface protection member 14 may be filled between the protection portion 15a of the frame 15 and the outer edge portion of the light-receiving-surface protection member 11.

### Other Embodiments

In the embodiments described thus far, blue plate glass is used as the light-receiving-surface protection member 11, whereas blue plate tempered glass is used as the rear-surface protection member 14. However, the present invention is not limited to this configuration.

For example, the present invention can employ a material having higher strength than that of the light-receiving-surface protection member 11 as the rear-surface protection member 14. The evaluation of strength can be made based on strength against impact obtained in the hail test defined in IEC 61215 10.17, for example. When blue plate glass is used as the light-receiving-surface protection member 11, for example, a metal plate such as an SUS plate, fiber-reinforced plastic, or the like may be used as the rear-surface protection member.

Further, without being limited to this embodiment, the present invention can employ a material having a smaller amount of displacement for a load than that of the light-receiving-surface protection member 11 as the rear-surface protection member 14. For example, a metal plate such as an SUS plate, fiber-reinforced plastic, or the like may be used as the rear-surface protection member 14. In addition, plastic or the like having such a structure that an amount of displacement would be suppressed with addition of ribs or the like can be employed as the rear-surface protection member 14.

Furthermore, in addition to a solar cell module employing a thin-film solar cell, the present invention is applicable to solar cell modules configured by employing various solar cells including a solar cell using a monocrystalline silicon wafer and a solar cell using a polycrystalline silicon wafer, and so forth.

Note that, the entire contents of Japanese Patent Application No. 2007-112266 (filed on Apr. 20, 2007) and Japanese Patent Application No. 2007-228151 (filed on Sep. 3, 2007) are incorporated herein by reference.

### INDUSTRIAL APPLICABILITY

As described above, the present invention can provide a solar cell module capable of suppressing damage, and thus is advantageous in the field of solar power generation.

1. A solar cell module comprising:
a transparent light-receiving-surface protection member including a light-receiving surface and a rear surface provided on a side opposite to the light-receiving surface;
a rear-surface protection member placed at the rear surface side of the light-receiving-surface protection member; and
a plurality of solar cells bonded between the light-receiving-surface protection member and the rear-surface protection member, wherein
the rear-surface protection member has a planar shape larger than that of the light-receiving-surface protection member, and has a smaller amount of displacement for an external load than that of the light-receiving-surface protection member.

2. A solar cell module comprising:
a transparent light-receiving-surface protection member including a light-receiving surface and a rear surface provided on a side opposite to the light-receiving surface;
a rear-surface protection member placed at the rear surface side of the light-receiving-surface protection member; and
a plurality of solar cells bonded between the light-receiving-surface protection member and the rear-surface protection member, wherein
the rear-surface protection member has a planar shape larger than that of the light-receiving-surface protection member, and has higher strength against impact than that of the light-receiving-surface protection member.

3. The solar cell module according to any one of claims 1 and 2, wherein the rear-surface protection member is made of glass.

4. The solar cell module according to any one of claims 1 and 2, wherein, on a projection plane substantially parallel to the light-receiving surface of the light-receiving-surface protection member, a frame holds a portion, in which the rear-surface protection member does not overlap the light-receiving-surface protection member, of the rear-surface protection member.

5. The solar cell module according to claim 4, wherein the light-receiving-surface protection member is smaller than an inside dimension of the frame.

6. The solar cell module according to claim 5, wherein a corner portion formed between the light-receiving surface of the light-receiving-surface protection member and an end surface continuous to the light-receiving surface is covered with a resin material.
